(19) United States
(12) Patent Application Publication
(10) Pub. No.: US 2004/0120394 A1
(43) Pub. Date: Jun. 24, 2004

(54) Decision-feedback equalizer

(76) Inventors: George J. Miao, Marlboro, NJ (US); Xiao-Feng Qi, Freehold, NJ (US)

Correspondence Address: BUCKLEY, MASCHOFF, TALWALKAR LLC, 5 ELM STREET, NEW CANAAN, CT, 06840, US

(21) Appl. No.: 10/323,025

(22) Filed: Dec. 18, 2002

(51) Int. Cl. H03K 5/159; H03H 7/30

(52) U.S. Cl. 375/234

(57) ABSTRACT

According to some embodiments, a decision-feedback equalizer is provided.

### BACKGROUND

A Decision-Feedback Equalizer (DFE) is a nonlinear equalizer that has both a feed-forward equalization filter and a feedback equalization filter. It is known that a DFE can be used to facilitate a detection of symbols associated with a stream of samples. For example, a DFE can be used to reduce mean-square Inter-Symbol Interference (ISI) when detecting symbols in a Digital Subscriber Line (DSL) transceiver.

FIG. 1 illustrates a typical DFE 100. The DFE 100 includes a feed-forward filter section 110 that receives samples s[n] and stores the samples in a buffer 112. Information in the buffer 112 is convoluted with information from a filter 114 having a function H₁(Z). The result x[n] of the convolution is then provided to a feedback filter section 130. The feed-forward filter section 110 is “T/2 spaced” (i.e., for every two samples s[n] that are received by the feed-forward filter section 110, one result x[n] is provided to the feedback filter section 130).

The feedback filter section 130 combines x[n] with information from a filter 136 having function H₂(Z) to generate d[n]. A symbol-by-symbol detector 132 then generates y[n] based on d[n] and a function Q{d[n]} as follows:

y[n] is equal to 1 if d[n]≧0; and

y[n] is equal to 0 if d[n]<0.

The y[n] value is provided to the filter 136 and is subtracted from d[n] to create an error signal e[n]. A Least Mean Square (LMS) algorithm unit 134 uses e[n] to adjust coefficients in the filters 114, 136. Note that the filters 114, 136 (as well as the buffer 112) may each include N taps (e.g., 136 taps)—and the LMS algorithm may adaptively adjust tap coefficients based on the use of (noise-corrupted) estimates of the gradients. Also note that the traditional DFE 100 can be computationally complex and require substantial processing power.

### BRIEF DESCRIPTION OF THE DRAWINGS

FIG. 1 illustrates a typical T/2 spaced binary decision DFE.

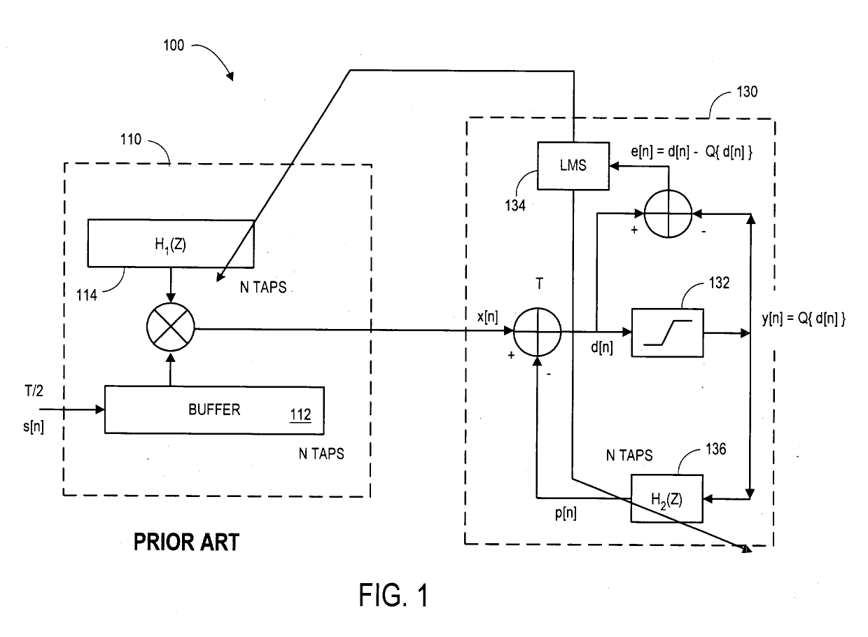

FIG. 2 is a block diagram of a DFE according to some embodiments.

FIG. 3 is a flow chart of a method according to some embodiments.

FIG. 4 is a more detailed block diagram of a DFE according to some embodiments.

FIG. 5 is a flow chart of a method according to some embodiments.

FIG. 6 is a block diagram of a DFE including a feed-forward filter section with an adaptive filter bank architecture in accordance with some embodiments.

FIG. 7 is a flow chart of a method according to some embodiments.

FIG. 8 is a system according to some embodiments.

### DETAILED DESCRIPTION

Some embodiments described herein are directed to a DFE. As used herein, a DFE may be associated with, for example, a DSL transceiver, a wireless system, or a cable modem. Moreover, a DFE may be implemented in hardware, such as in an Application Specific Integrated Circuit (ASIC) device, software, or a combination of hardware and software.

### Decision-Feedback Equalizer Having MT/N Spaced Feed-Forward Filter Section

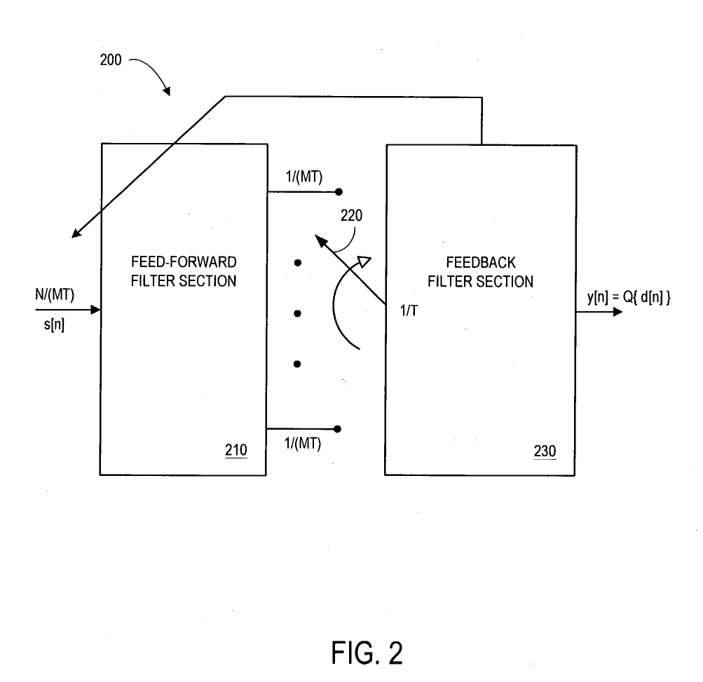

FIG. 2 is a block diagram of a DFE 200 according to some embodiments. The DFE 200 includes a feed-forward filter section 210 that receives samples s[n] and provides information to a feedback filter section 230 via a switch 220 having M switch positions. The feed-forward filter section 210 is “MT/N spaced,” where M and N are integers, N is greater than M, and N is greater than two (i.e., for every N samples s[n] that are received, M results x[n] are provided to the feedback filter section 130). The feedback filter section 230 receives information via the switch 220, generates y[n], and adjusts filter coefficients in the feed-forward filter section 210. Note that the filter coefficients and the received samples may comprise complex data.

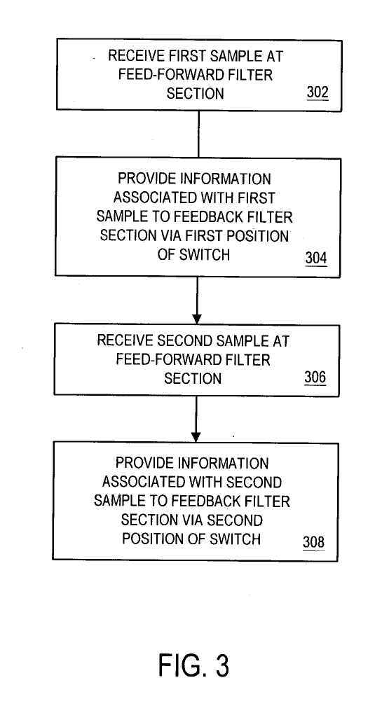

Refer now to FIG. 3, which is a flow chart of a method according to some embodiments. The flow chart does not imply a fixed order to the actions, and embodiments may be practiced in any order that is practicable. The method may be associated with, for example, the DFE 200 described with respect to FIG. 2.

At 302, a first sample is received at the feed-forward filter section 210. At 304, information associated with the first sample is provided the feedback filter section 230 via a first position of the switch 220. For example, the feed-forward filter section 210 may convolute the first sample with information from a filter to generate the information that is provided to the feedback filter section 230. Similarly, a second sample is received at the feed-forward filter section 210 at 306. Information associated with the second sample is then provided the feedback filter section 230 via a second position of the switch 220 at 308. Note that the method of FIG. 3 may be associated with any MT/N spaced feed-forward filter section (i.e., the switch 220 might have more than two switch positions).

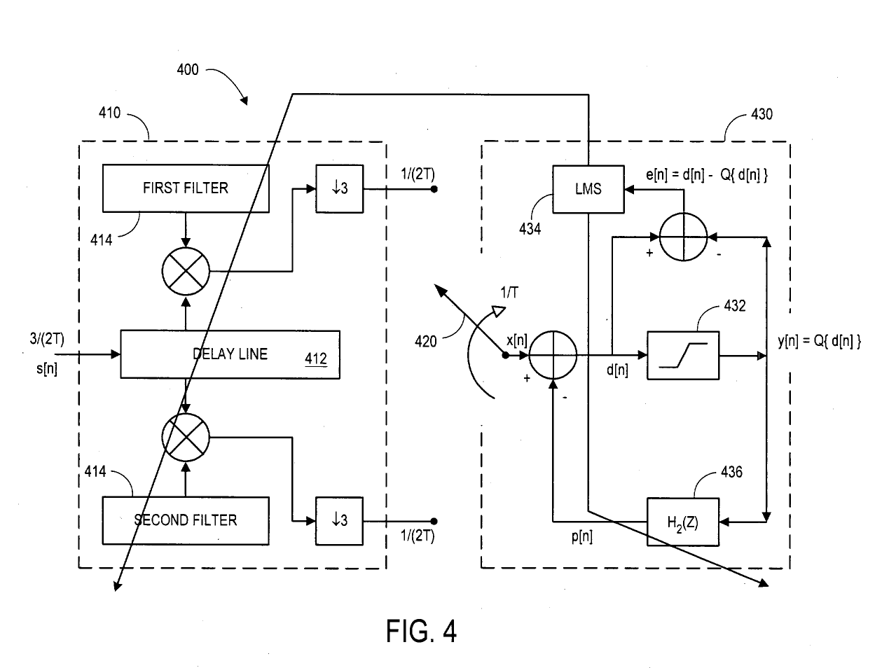

FIG. 4 is a more detailed block diagram of a DFE 400 according to some embodiments. The DFE 400 includes a feed-forward filter section 410 that receives samples s[n] and stores the samples in a delay line 412. Samples in the delay line 412 may be convoluted with information from one of two filters 414, and the result is down sampled by a factor of three before being provided to a two-position switch 420. Information output by the switch 420, referred to as x[n], is then provided to the feedback filter section 430.

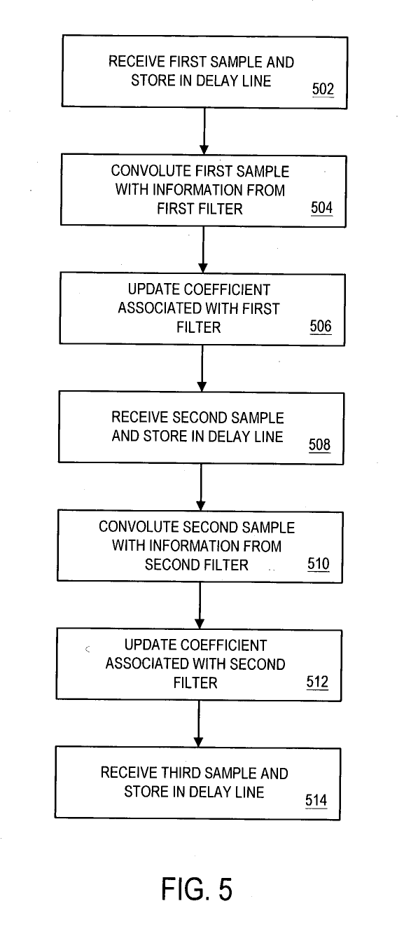

According to this embodiment, the feed-forward filter section 110 is “2T/3 spaced” (i.e., for every three samples s[n] that are received by the feed-forward filter section 410, two results are provided to the feedback filter section 430). Refer now to FIG. 5, which is a flow chart of a method according to some embodiments. At 502, a first sample is received and stored in the delay line 412. At 504, the first sample is convoluted with information from the first filter 414. Information associated with the convolution is then provided to the feedback filter section 430 via the switch 420 (e.g., the switch 420 would be in the upper position to receive x[n]). At 506, a coefficient associated with the first filter 414 is updated by the feedback filter section 430 (e.g., the coefficient may be increased or decreased by a pre-determined amount).

At 508, a second sample is received and stored in the delay line 412. At 510, the second sample is convoluted with information from the second filter 414. Information associated with the convolution is then provided to the feedback filter section 430 via the switch 420 (e.g., the switch 420 would now be in the lower position to receive x[n]). At 512, a coefficient associated with the second filter 414 is updated by the feedback filter section 430.

At 514, a third sample is received and stored in the delay line 412. The DFE 400 then takes no further action with respect to this third sample. The process continues as additional samples are received (e.g., a fourth sample would be processed in the same way as the first sample). Thus, for every three samples s[n] that are received, two results x[n] are provided to the feedback filter section 430.

Referring again to FIG. 4, the feedback filter section 430 combines x[n] with information from a filter 436 having a function H₂(Z) to generate d[n]. A symbol-by-symbol detector 432 then generates y[n] based on d[n] and a function Q{d[n]} as follows:

y[n] is equal to 1 if d[n]≧0; and

y[n] is equal to 0 if d[n]<0.

The y[n] value is provided to the filter 436 and is subtracted from d[n] to create an error signal e[n]. A LMS algorithm unit 434 uses e[n] to adjust coefficients used by the filter 436 in the feedback filter section 430. The LMS algorithm unit 434 may also adjust either the first or second filter 414 in the feed-forward filter section 410 as appropriate (e.g., based on the switch position that received x[n]).

According to some embodiments, the filters 414 in the feed-forward filter section 410 have fewer taps as compared to the filter 114 of the T/2 spaced feed-forward filter section 110. As a result, the DFE 400 may be less computationally complex (and require less processing power) as compared to a traditional DFE. For example, the filters 414 in the feed-forward filter section 410 might only need 102 taps while the filter 114 in the traditional T/2 spaced feed-forward filter section 110 required 136 taps (note that the filter 436 and the filter 136 in the feedback filter sections 430, 130 might both require 136 taps). In this case, the 2T/3 spaced DFE 400 may save 25% in terms of Multiply And Accumulate (MAC) complexity per symbol.

According to some embodiments, a number of samples are used to train the DFE 400. For example, a first set of 300,000 samples might be provided to the DFE 400. While samples in the first set are processed, a particular step size may be associated with coefficient adjustments for the first and second filters 414 (and another step size might be associated with adjustments for the filter 436 in the feedback filter section 430). Another set of 1,800,000 might then be provided to the DFE 400 and different (e.g., smaller) step-sizes may be used to adjust filter coefficients. This training process may be repeated until the DFE 400 accomplishes a desired Signal-to-Noise Ratio (SNR), such as 22.2 decibels (dB).

### Adaptive Filter Bank Architecture

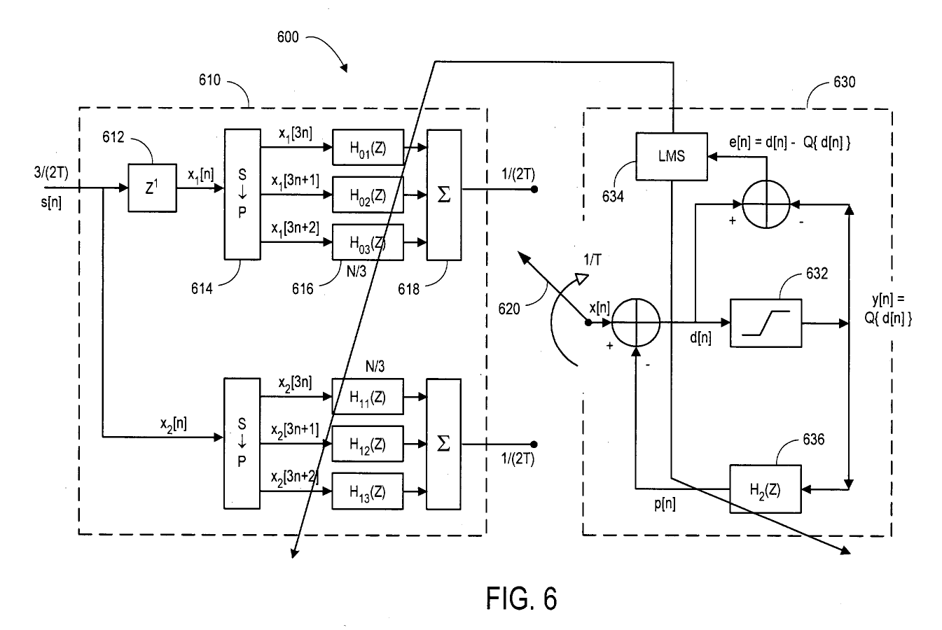

FIG. 6 is a block diagram of a DFE 600 including a 2T/3 spaced feed-forward filter section 610 with an adaptive filter bank architecture in accordance with some embodiments. As before, the feed-forward filter section 610 provides information to a feedback filter section 630 via a two-position switch 620.

The feed-forward filter section 610 creates two sets of data (x₁[n] and x₂[n]) based on an input sample s[n]. In particular, a delay element 612 (associated with function Z¹) introduces a one sample delay to create x₁[n] and no delay is introduced to create x₂[n].

The first set of data x₁[n] is processed at a first filter branch that includes a serial-to-parallel element 614. The serial-to-parallel element 614 divides x₁[n] into three sample portions (x₁[3n], x₁[3n+1], and x₁[3n+2]), each sample portion being one-third as long as x₁[n] (i.e., when the length of x₁[n] is N, the length of each sample portion is N/3). The three sample portions are simultaneously processed by a bank of three adaptive filters 616 (associated with functions H₀₁(Z), H₀₂(Z), and H₀₃(Z), respectively). A summation element 616 adds information from the three filters 616 and provides the result (2T spaced) via a first position of the switch 620.

Similarly, the second set of data x₂[n] is processed at a second filter branch that includes a serial-to-parallel element. That serial-to-parallel element divides x₂[n] into three sample portions (x₂[3n], x₂[3n+1], and x₂[3n+2]), each sample portion being one-third as long as x₂[n] (i.e., when the length of x₂[n] is N, the length of each sample portion is N/3). The three sample portions are simultaneously processed by a bank of three adaptive filters (associated with functions H₁₁(Z), H₁₂(Z), and H₁₃(Z), respectively). Note that all six filters (i.e., the three in the top filter branch and the three in the bottom filter branch) may process information at the same discrete-time index. A summation element adds information from these three filters and provides the result (2T spaced) via a second position of the switch 620.

Information from the switch 620 (now T spaced) is combined at the feedback filter section 630 with information from a filter 636 having a function H₂(Z) to generate d[n]. A symbol-by-symbol detector 632 then generates y[n] based on d[n] and function Q{d[n]}.

The y[n] value is provided to the filter 636 and is subtracted from d[n] to create an error signal e[n]. A LMS algorithm unit 634 uses e[n] to adjust coefficients used by the filter 636 in the feedback filter section 630. The LMS algorithm unit 634 may also adjust coefficients associated with the three adaptive filters 616 in the first filter branch or the three adaptive filters in the second filter branch (e.g., based on the switch position that received x[n]).

Because the length of each sample portion is only one-third that of the original sample, the number of filter taps in the adaptive filters 616 may be reduced. Recall that the 2T/3 spacing of the feed-forward filter section 610 allows for a 25% reduction in the number of filter taps as compared with a traditional DFE (e.g., from 136 taps to 102 taps in the example described with respect to FIG. 4). The adaptive filter bank approach may reduce the number of taps even further. For example, if 102 taps would have been required, the adaptive filter bank approach may simultaneously process data using six filters, each filter having 17 taps. As a result, the computational complexity (and required processing power) associated with the DFE may be reduced because the filter bank approach provides a more efficient parallel architecture implementation for a DFE.

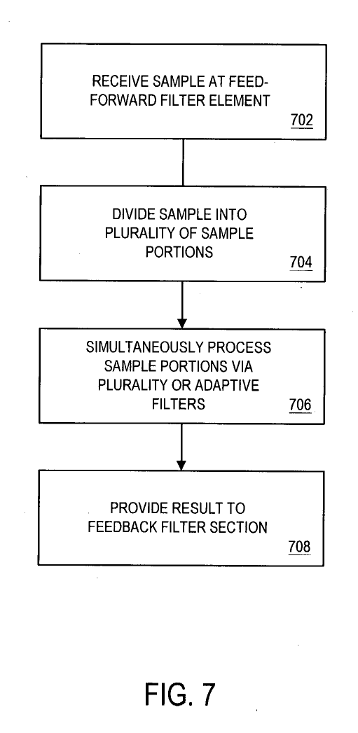

FIG. 7 is a flow chart of a method according to some embodiments. At 702, a sample is received at a feed-forward filter section. The sample is then divided into a plurality of sample portions at 704. For example, two data sets may be created based on the received sample (e.g., by introducing a one sample delay to create a data set). The first data set may then be divided (e.g., by a serial-to-parallel element) into three sample portions that will be simultaneously processed via a first filter branch. The second data set may also be divided into three sample portions to be simultaneously processed via a second filter branch.

At 706, the sample portions are simultaneously processed via a plurality of adaptive filters. A result is then provided to a feedback filter section at 708. For example, the result may be provided from one of a first or second filter branch via a two-position switch.

### System

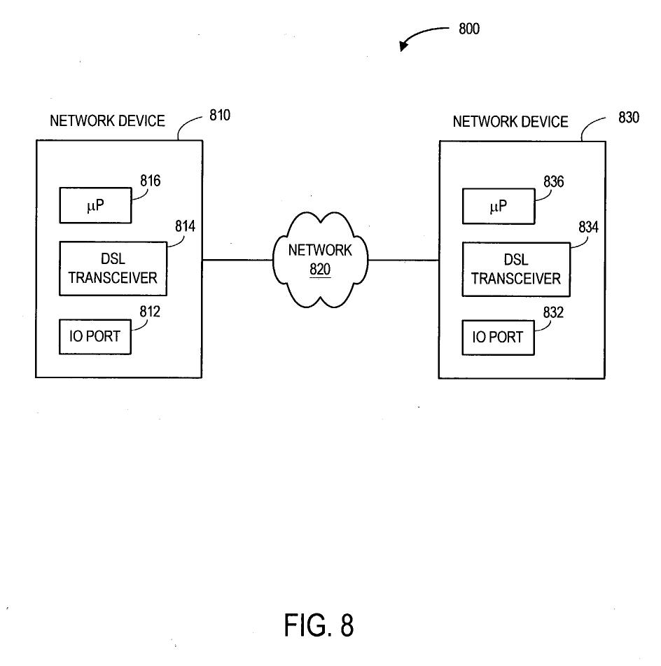

FIG. 8 is a system 800 according to some embodiments. In particular, a first network device 810 communicates with a second network device 830 via a network 820. The first network device 810 includes an Input Output (IO) port 812, a DSL transceiver 814, and a microprocessor 816. The microprocessor 816 may, for example, execute an application that exchanges data via the IO port 812. Similarly, the second network device 830 includes an IO port 832, a DSL transceiver 834, and a microprocessor 836. Moreover, the first network device 810 and/or the second network device 830 may operate in accordance with any of the embodiments described herein. For example, the DSL transceiver 814 may include a feedback filter section, a switch to provide information to the feedback filter section, and an MT/N spaced feed-forward filter section to provide information to the switch, where M and N are integers, N is greater than M, and N is greater than two.

### Additional Embodiments

The following illustrates various additional embodiments. These do not constitute a definition of all possible embodiments, and those skilled in the art will understand that many other embodiments are possible. Further, although the following embodiments are briefly described for clarity, those skilled in the art will understand how to make any changes, if necessary, to the above description to accommodate these and other embodiments and applications.

Although particular examples of MT/N spaced feed-forward filter sections have been provided (e.g., 2T/3), embodiments may be associated with other spacing (e.g., 3T/4). Moreover, although the adaptive filter bank architecture was illustrated with respect to a 2T/3 spaced feed-forward filter section, embodiments may be associated with other spacing (including the traditional T/2 spacing).

The several embodiments described herein are solely for the purpose of illustration. Persons skilled in the art will recognize from this description other embodiments may be practiced with modifications and alterations limited only by the claims.

What is claimed is:

1. An apparatus, comprising:
a feedback filter section;
a switch to provide information to the feedback filter section; and
an MT/N spaced feed-forward filter section to provide information to the switch, where M and N are integers, N is greater than M, and N is greater than two.

2. The apparatus of claim 1, wherein the feed-forward filter section is 2T/3 spaced.

3. The apparatus of claim 1, wherein the feedback filter section is T spaced.

4. The apparatus of claim 1, wherein the apparatus comprises an adaptive decision-feedback equalizer.

5. The apparatus of claim 4, wherein the adaptive decision-feedback equalizer is associated with a digital subscriber line transceiver.

6. The apparatus of claim 1, wherein the feed-forward filter section includes:
a delay line to store samples; and
M filters, wherein samples from the delay line are to be convoluted with information from sequentially selected filters before being provided to the switch.

7. The apparatus of claim 6, wherein the feedback filter section includes:
a least mean square algorithm unit to adaptively adjust a coefficient and to provide the adjusted coefficient to an associated filter in the feed-forward filter section.

8. The apparatus of claim 7, wherein the least mean square algorithm unit also adjusts a coefficient of a filter in the feedback filter section.

9. The apparatus of claim 1, wherein the apparatus is associated with at least one of: (i) an application specific integrated circuit, and (ii) a cable modem transceiver.

10. An adaptive decision-feedback equalizer, comprising:
a T spaced feedback filter section, including a least mean square algorithm unit to adaptively adjust a coefficient of a filter in the feedback filter section;
a switch to provide information to the feedback filter section; and
an 2T/3 spaced feed-forward filter section to provide information to the switch, comprising:
a delay line to store samples, and
two filters each having a coefficient that can be adjusted by the least mean square algorithm unit, wherein samples from the delay line are to be convoluted with information from sequentially selected filters before being provided to the switch.

11. The adaptive decision-feedback equalizer of claim 10, wherein the adaptive decision-feedback equalizer is associated with a digital subscriber line transceiver.

12. A method, comprising:
receiving a first sample at an MT/N spaced feed-forward filter section in an adaptive decision-feedback equalizer, where M and N are integers, N is greater than M, and N is greater than two;
convoluting the first sample with information from a first filter and providing the result to a feedback filter section in the adaptive decision-feedback equalizer; and
updating a coefficient associated with the first filter based on information received from the feedback filter section.

13. The method of claim 12, further comprising:
storing the first sample in a delay line.

14. The method of claim 13, further comprising:
receiving a second sample at the feed-forward filter section;
storing the second sample in the delay line;
convoluting the second sample with information from a second filter and providing the result to the feedback filter section;
updating a coefficient associated with the second filter based on information received from the feedback filter section;
receiving a third sample at the feed-forward filter section; and
storing the third sample in the delay line, wherein information associated with the third sample is not provided to the feedback filter section.

15. The method of claim 12, further comprising:
training the adaptive decision-feedback equalizer.

16. A medium storing instructions adapted to be executed by a processor to perform a method, said method comprising:
receiving a first sample at an MT/N spaced feed-forward filter section in an adaptive decision-feedback equalizer, where M and N are integers, N is greater than M, and N is greater than two;
convoluting the first sample with information from a first filter and providing the result to a feedback filter section in the adaptive decision-feedback equalizer; and
updating a coefficient associated with the first filter based on information received from the feedback filter section.

17. The medium of claim 16, wherein said method further comprises:
storing the first sample in a delay line.

18. The medium of claim 17, wherein said method further comprises:
receiving a second sample at the feed-forward filter section;
storing the second sample in the delay line;
convoluting the second sample with information from a second filter and providing the result to the feedback filter section;
updating a coefficient associated with the second filter based on information received from the feedback filter section;
receiving a third sample at the feed-forward filter section; and
storing the third sample in the delay line, wherein information associated with the third sample is not to be provided to the feedback filter section.

19. The medium of claim 16, wherein said method further comprises:
training the adaptive decision-feedback equalizer.

20. An apparatus, comprising:
a feedback filter section; and
a feed-forward filter section, the feed-forward filter section including a plurality of parallel adaptive filters.

21. The apparatus of claim 20, wherein the feed-forward filter section is 2T/3 spaced.

22. The apparatus of claim 21, further comprising:
a two-position switch to provide information from the feed-forward filter section to the feedback filter section.

23. The apparatus of claim 22, wherein the feed-forward filter section comprises:
a first filter branch, including:
a delay element,
a first serial-to-parallel element to divide information received from the delay element into three sample portions,
a first set of three adaptive filters, each adaptive filter being associated with one of the sample portions, and
a first summation element to add information received from the three adaptive filters and to provide a result via a first position of the switch; and
a second filter branch, including:
a second serial-to-parallel element to divide information associated with a sample into three sample portions,
a second set of three adaptive filters, each adaptive filter being associated with one of the sample portions, and
a second summation element to add information received from the three adaptive filters and to provide a result to a second position of the switch.

24. The apparatus of claim 23, wherein coefficients associated with the first set of adaptive filters are updated based on the result provided via the first position of the switch and coefficients associated with the second set of adaptive filters are updated based on the result provided via the second position of the switch.

25. A method, comprising:
receiving a sample at a feed-forward filter section;
dividing the sample into a plurality of sample portions;
simultaneously processing the sample portions via a plurality of adaptive filters; and
providing a result to a feedback filter section.

26. The method of claim 25, further comprising:
creating two data sets based on the received sample, wherein the first data set is divided into three sample portions that are simultaneously processed via a first filter branch and the second data set is divided into three sample portions that are simultaneously processed via a second filter branch.

27. The method of claim 26, wherein said creating comprises introducing a one sample delay.

28. The method of claim 27, wherein said dividing is performed by a serial-to-parallel element.

29. The method of claim 28, wherein said providing is performed from the first or second filter branch via a two-position switch.

30. A medium storing instructions adapted to be executed by a processor to perform a method, said method comprising:
receiving a sample at a feed-forward filter section;
dividing the sample into a plurality of sample portions;
simultaneously processing the sample portions via a plurality of adaptive filters; and
providing a result to a feedback filter section.

31. The medium of claim 30, wherein said method further comprises:
creating two data sets based on the received sample, wherein the first data set is divided into three sample portions that are simultaneously processed via a first filter branch and the second data set is divided into three sample portions that are simultaneously processed via a second filter branch.

32. The medium of claim 31, wherein said creating comprises introducing a one sample delay.

33. The medium of claim 32, wherein said dividing is performed by a serial-to-parallel element.

34. The medium of claim 33, wherein said providing is performed from the first or second filter branch via a two-position switch.

35. A system, comprising:
a main processor to execute an application that exchanges data via a network; and
a transceiver, including:
a feedback filter section;
a switch to provide information to the feedback filter section; and
an MT/N spaced feed-forward filter section to provide information to the switch, where M and N are integers, N is greater than M, and N is greater than two.

36. The system of claim 35, wherein the transceiver comprises a digital subscriber line transceiver.
